(19) United States
(12) Patent Application Publication
(10) Pub. No.: US 2024/0355532 A1
(43) Pub. Date: Oct. 24, 2024

(54) COIL, INDUCTOR COMPONENT, AND INDUCTOR ARRAY

(71) Applicant: Murata Manufacturing Co,. Ltd., Nagaokakyo-shi (JP)

(72) Inventors: Yoshimitsu USHIMI, Nagaokakyo-shi (JP); Koshi Himeda, Nagaokakyo-shi (JP); Kenji Nishiyama, Nagaokakyo-shi (JP); Hidehiko Sasaki, Nagaokakyo-shi (JP); Nobuyoshi Adachi, Nagaokakyo-shi (JP)

(21) Appl. No.: 18/761,609

(22) Filed: Jul. 2, 2024

Related U.S. Application Data
(63) Continuation of application No. PCT/JP2023/002484, filed on Jan. 26, 2023.

(30) Foreign Application Priority Data
Feb. 7, 2022 (JP) 2022-017329

(51) Int. Cl. H01F 27/28; H01F 27/24

(52) U.S. Cl. CPC H01F 27/2823; H01F 27/24

(57) ABSTRACT

A coil that includes a coil wire spirally wound along an axis. The coil wire includes a first wiring portion and a second wiring portion which are aligned along the axis. The first wiring portion includes a first end surface on a side in a first direction from the first wiring portion toward the second wiring portion, and a second end surface on a side in a second direction opposite to the first direction. The first end surface includes a first end in an inner side portion in a radial direction of the coil wire. The second end surface is in an outer side portion in the radial direction of the coil wire with respect to a straight line passing through the first end and parallel to the direction of the axis.

### CROSS REFERENCE TO RELATED APPLICATIONS

The present application is a continuation of International application No. PCT/JP2023/002484, filed Jan. 26, 2023, which claims priority to Japanese Patent Application No. 2022-017329, filed Feb. 7, 2022, the entire contents of each of which are incorporated herein by reference.

### TECHNICAL FIELD

The present disclosure relates to a coil, an inductor component, and an inductor array.

### BACKGROUND ART

In recent years, size reduction of electronic devices such as game machines and mobile phones has been accelerated, and as a result, there is an increasing demand for a reduced and thinner size of elements using various coils of inductors mounted on electronic devices.

In addition, various elements used in a power supply line that supplies power to a load such as a processor are disposed in the vicinity of the load. In this manner, a loss can be reduced. Therefore, for example, since the elements need to be incorporated into a substrate on which the load is mounted, there is a strong demand for a further reduced and thinner size.

In view of this background, there is a demand for a thinner coil used in an element such as an inductor or a transformer.

In the related art, Japanese Unexamined Patent Application Publication No. 2016-136556 (Patent Document 1) (discloses the coil. This coil is formed by spirally winding a flat (flat plate-shaped) coil conductor along an axis.

### SUMMARY OF THE DISCLOSURE

Incidentally, for example, when a size of the coil as in the related art is simply reduced by reducing a coil diameter, an area of an inner magnetic path portion of the coil is reduced, and coil characteristics deteriorate. Therefore, there is a limit in achieving both the size reduction and the coil characteristics.

Therefore, the present disclosure aims to provide a coil, an inductor component, and an inductor array which can achieve both size reduction and coil characteristics.

According to one aspect of the present disclosure, in order to solve the above-described problem, there is provided a coil including a coil wire spirally wound along an axis. In a cross section including the axis, the coil wire includes a first wiring portion and a second wiring portion which are aligned along the axis. The first wiring portion is in a first outermost side portion in a direction of the axis, and the second wiring portion is in a second outermost side portion in the direction of the axis. The first wiring portion includes a first end surface on a side in a first direction from the first wiring portion toward the second wiring portion which is the direction of the axis, and a second end surface on a side in a second direction opposite to the first direction. The second wiring portion includes a third end surface on the side in the first direction, and a fourth end surface on the side in the second direction. The first end surface includes a first end in an inner side portion in a radial direction of the coil wire. The second end surface is in an outer side portion in the radial direction of the coil wire with respect to a straight line passing through the first end and parallel to the direction of the axis.

According to the aspect, in the cross section including the axis of the coil, the second end surface is located in the outer side portion in the radial direction of the coil wire with respect to the straight line passing through the first end and parallel to the direction of the axis. Therefore, it is possible to reduce a possibility that a magnetic flux generated from the coil enters the coil wire. In this manner, it is possible to suppress a possibility that the magnetic flux is hindered by the coil wire, and coil characteristics can be improved, compared to more than the flat coil in the related art. As a result, compared to the flat coil in the related art, for example, even when the size of the coil is reduced by reducing a coil diameter, the coil characteristics equal to those in the related art can be achieved. Therefore, it is possible to achieve both the size reduction and the coil characteristics.

Preferably, in one embodiment of the coil, in the cross section including the axis, the first end surface includes a second end in the outer side portion in the radial direction of the coil wire, and the second end surface is in the inner side portion in the radial direction of the coil wire with respect to a straight line passing through the second end and parallel to the direction of the axis.

According to the embodiment, it is possible to further suppress a possibility that the magnetic flux is hindered by the coil wire, and it is possible to further improve the coil characteristics, compared to the flat coil in the related art. As a result, it is possible to more effectively achieve both size reduction and the coil characteristics.

Preferably, in one embodiment of the coil, in the cross section including the axis, a length of the second end surface is shorter than a length of the first end surface.

According to the embodiment, it is possible to more effectively suppress a possibility that the magnetic flux is hindered by the coil wire, and the coil characteristics can be further improved, compared to the flat coil in the related art. As a result, even when the size of the coil is further reduced compared to the flat coil in the related art, the coil characteristics equal to those in the related art can be achieved. Therefore, it is possible to more easily achieve both the size reduction and the coil characteristics.

Preferably, in one embodiment of the coil, in the cross section including the axis, the length of the second end surface is equal to or longer than 80% and equal to or shorter than 95% of the length of the first end surface.

According to the embodiment, it is possible to more easily achieve both the size reduction and the coil characteristics.

Preferably, in one embodiment of the coil, in the cross section including the axis, the fourth end surface includes a third end in the inner side portion in the radial direction. The third end surface is in the outer side portion in the radial direction with respect to a straight line passing through the third end and parallel to the direction of the axis.

According to the embodiment, even when the size of the coil is reduced, the coil characteristics equal to those of the coil in the related art can be more easily achieved. Therefore, it is possible to more easily achieve both the size reduction and the coil characteristics.

Preferably, in one embodiment of the coil, in the cross section including the axis, the fourth end surface includes a fourth end located in an outer side portion in the radial direction of the coil wire. The third end surface is in an inner side portion in the radial direction of the coil wire with respect to a straight line passing through the fourth end and parallel to the direction of the axis.

According to the embodiment, it is possible to further suppress a possibility that the magnetic flux is hindered by the coil wire, and it is possible to further improve the coil characteristics, compared to the flat coil in the related art. As a result, it is possible to more effectively achieve both size reduction and the coil characteristics.

Preferably, in one embodiment of the coil, in the cross section including the axis, a length of the third end surface is shorter than a length of the fourth end surface.

According to the embodiment, it is possible to more effectively suppress a possibility that the magnetic flux is hindered by the coil wire, and the coil characteristics can be further improved, compared to the flat coil in the related art. As a result, even when the size of the coil is further reduced compared to the flat coil in the related art, the coil characteristics equal to those in the related art can be achieved. Therefore, it is possible to more easily achieve both the size reduction and the coil characteristics.

Preferably, in one embodiment of the coil, in the cross section including the axis, the length of the third end surface is equal to or longer than 80% and equal to or shorter than 95% of the length of the fourth end surface.

According to the embodiment, it is possible to more easily achieve both the size reduction and the coil characteristics.

Preferably, in one embodiment of the coil, in the cross section including the axis, the coil wire further includes a third wiring portion between the first wiring portion and the second wiring portion.

According to the embodiment, the number of turns of the coil can be increased.

Preferably, in one embodiment of the coil, in the cross section including the axis, a length of the first end surface is equal to a maximum width of the third wiring portion in the radial direction of the coil wire, or is shorter than the maximum width of the third wiring portion.

According to the embodiment, in the cross section including the axis, the length of the first end surface is equal to the maximum width of the third wiring portion in the radial direction of the coil wire, or is shorter than the maximum width of the third wiring portion. Therefore, in the cross section including the axis, it is possible to reduce a possibility that the magnetic flux generated from the coil enters the coil wire, compared to when the length of the first end surface is longer than the maximum width of the third wiring portion in the radial direction of the coil wire. In this manner, even when the coil wire includes the third wiring portion, it is possible to achieve both the size reduction and the coil characteristics.

Preferably, in one embodiment of the coil, in the cross section including the axis, a length of the fourth end surface is equal to a maximum width of the third wiring portion in the radial direction of the coil wire, or is shorter than the maximum width of the third wiring portion.

According to the embodiment, in the cross section including the axis, the length of the fourth end surface is equal to the maximum width of the third wiring portion in the radial direction of the coil wire, or is shorter than the maximum width of the third wiring portion. Therefore, in the cross section including the axis, a volume of a coil wire portion present in a path of the magnetic flux generated from the coil can be reduced, compared to when the length of the fourth end surface is longer than the maximum width of the third wiring portion in the radial direction of the coil wire. In this manner, even when the coil wire includes the third wiring portion, it is possible to achieve both the size reduction and the coil characteristics.

Preferably, in one embodiment of the coil, in the cross section including the axis, the third wiring portion includes a fifth end surface on a side in the first direction, and a sixth end surface on a side in the second direction. A length of the sixth end surface is shorter than a length of the fifth end surface, and is equal to the length of the first end surface, or is longer than the length of the first end surface.

According to the embodiment, it is possible to more effectively suppress a possibility that the magnetic flux is hindered by the coil wire. Therefore, it is possible to more easily achieve both the size reduction and the coil characteristics.

Preferably, in one embodiment of the coil, in the cross section including the axis, a thickness of the first wiring portion is thicker than a thickness of the third wiring portion.

According to the embodiment, electrical resistance of the coil wire can be reduced.

Preferably, in one embodiment of the coil, in the cross section including the axis, a cross-sectional area of the first wiring portion is equal to or more than 0.8 times and equal to or less than 1.2 times a cross-sectional area of the third wiring portion.

According to the embodiment, the cross-sectional area of the first wiring portion can be equal to the cross-sectional area of the third wiring portion. Therefore, electrical resistance can be constant over the entire length of the coil wire.

Preferably, in one embodiment of the coil, in the cross section including the axis, the coil wire further includes a fourth wiring portion between the third wiring portion and the second wiring portion. A length of the first end surface is equal to a maximum width of the fourth wiring portion in the radial direction of the coil wire, or is shorter than the maximum width of the fourth wiring portion. A length of the fourth end surface is equal to the maximum width of the fourth wiring portion in the radial direction of the coil wire, or is shorter than the maximum width of the fourth wiring portion.

According to the embodiment, in the cross section including the axis, it is possible to reduce a possibility that the magnetic flux generated from the coil enters the coil wire, compared to when each length of the first end surface and the fourth end surface is longer than the maximum width of the fourth wiring portion of the coil wire in the radial direction of the coil wire. In this manner, even when the coil wire includes the fourth wiring portion, it is possible to achieve both the size reduction and the coil characteristics.

Preferably, in one embodiment of the coil, in the cross section including the axis, the fourth wiring portion includes a seventh end surface on the side in the first direction and an eighth end surface on the side in the second direction. A length of the seventh end surface is shorter than a length of the eighth end surface, and is equal to the length of the fourth end surface, or is longer than the length of the fourth end surface.

According to the embodiment, it is possible to more effectively suppress a possibility that the magnetic flux is hindered by the coil wire. Therefore, it is possible to more easily achieve both the size reduction and the coil characteristics.

Preferably, in one embodiment of the coil, in the cross section including the axis, a thickness of the first wiring portion is thicker than each thickness of the third wiring portion and the fourth wiring portion. A thickness of the second wiring portion is thicker than each thickness of the third wiring portion and the fourth wiring portion.

According to the embodiment, electrical resistance of the coil wire can be reduced.

Preferably, in one embodiment of the coil, in the cross section including the axis, a cross-sectional area of the first wiring portion is equal to or more than 0.8 times and equal to or less than 1.2 times each cross-sectional area of the third wiring portion and the fourth wiring portion. A cross-sectional area of the second wiring portion is equal to or more than 0.8 times and equal to or less than 1.2 times each cross-sectional area of the third wiring portion and the fourth wiring portion.

According to the embodiment, each cross-sectional area of the first wiring portion and the second wiring portion can be equal to each cross-sectional area of the third wiring portion and the fourth wiring portion. Therefore, electrical resistance can be constant over the entire length of the coil wire.

Preferably, in one embodiment of an inductor component, the inductor component includes an element body including a magnetic material, and the coil disposed inside the element body.

According to the embodiment, it is possible to suppress a possibility that the magnetic flux is hindered by the coil wire. Therefore, it is possible to achieve both the size reduction and an inductance value.

Preferably, in one embodiment of the inductor component, in the cross section including the axis, the first wiring portion includes a first side surface and a second side surface which connect the first end surface and the second end surface. The second wiring portion includes a third side surface and a fourth side surface which connect the third end surface and the fourth end surface. At least one side surface of the first side surface, the second side surface, the third side surface, and the fourth side surface has a recessed shape recessed inward of the first wiring portion or the second wiring portion.

According to the embodiment, a contact area between the coil wire and the element body is increased, and close contact between the coil wire and the element body is improved. Therefore, mechanical strength of the inductor component can be improved.

Preferably, in one embodiment of an inductor array, the inductor array includes a plurality of the inductor components. The plurality of inductor components are arrayed on the same plane.

According to the embodiment, it is possible to achieve both the size reduction and the inductance value of the inductor component. Therefore, it is possible to achieve both the size reduction and the inductance value in the inductor array as well.

According to the coil, the inductor component, and the inductor array in one aspect of the present disclosure, it is possible to achieve both the size reduction and the coil characteristics.

### BRIEF DESCRIPTION OF THE DRAWINGS

FIG. 1 is a plan view showing a first embodiment of an inductor component.

FIG. 2 is a cross-sectional view taken along line A-A in FIG. 1.

FIG. 3 is a cross-sectional view taken along line B-B in FIG. 1.

FIG. 4 is an exploded plan view of a coil wire.

FIG. 5 is an enlarged view of an A portion in FIG. 2.

FIG. 6 is an enlarged view of a B portion in FIG. 2.

FIG. 7A is a cross-sectional view for describing a manufacturing method for a coil.

FIG. 7B is a cross-sectional view for describing a manufacturing method for the coil.

FIG. 7C is a cross-sectional view for describing a manufacturing method for the coil.

FIG. 7D is a cross-sectional view for describing a manufacturing method for the coil.

FIG. 7E is a cross-sectional view for describing a manufacturing method for the coil.

FIG. 7F is a cross-sectional view for describing a manufacturing method for the coil.

FIG. 7G is a cross-sectional view for describing a manufacturing method for the coil.

FIG. 7H is a cross-sectional view for describing a manufacturing method for the coil.

FIG. 7I is a cross-sectional view for describing a manufacturing method for a coil.

FIG. 7J is a cross-sectional view for describing a manufacturing method for the coil.

FIG. 7K is a cross-sectional view for describing a manufacturing method for the coil.

FIG. 7L is a cross-sectional view for describing a manufacturing method for the coil.

FIG. 7M is a cross-sectional view for describing a manufacturing method for the coil.

FIG. 8 is a cross-sectional view showing a second embodiment of the coil.

FIG. 9 is a cross-sectional view showing a third embodiment of the coil.

FIG. 10 is a cross-sectional view showing a fourth embodiment of the coil.

FIG. 11 is a plan view showing a fifth embodiment of the coil.

FIG. 12 is a cross-sectional view taken along line A-A in FIG. 11.

FIG. 13A is a cross-sectional view for describing a manufacturing method for the coil.

FIG. 13B is a cross-sectional view for describing a manufacturing method for the coil.

FIG. 14 is a plan view showing an embodiment of an inductor component.

FIG. 15 is a cross-sectional view taken along line A-A in FIG. 14.

FIG. 16 is a cross-sectional view taken along line B-B in FIG. 14.

FIG. 17 is a cross-sectional view taken along line C-C in FIG. 14.

FIG. 18 is a cross-sectional view showing an embodiment of the inductor component.

FIG. 19 is a plan view showing an embodiment of an inductor array.

FIG. 20 is a cross-sectional view showing a state where the inductor array is incorporated into a substrate.

FIG. 21 is a plan view showing an embodiment of the inductor array.

### DESCRIPTION OF THE PREFERRED EMBODIMENTS

Hereinafter, a coil, an inductor component, and an inductor array according to an aspect of the present disclosure will be described in detail with reference to embodiments shown in the drawings. The drawings partially include schematic configurations, and do not reflect actual dimensions or ratios in some cases.

### First Embodiment

### (Configuration)

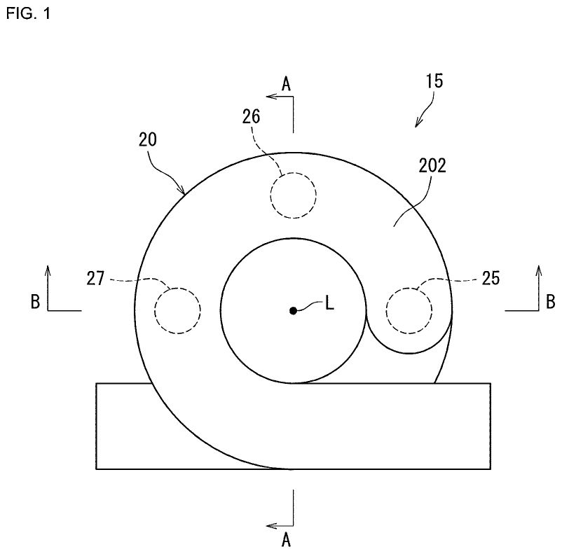

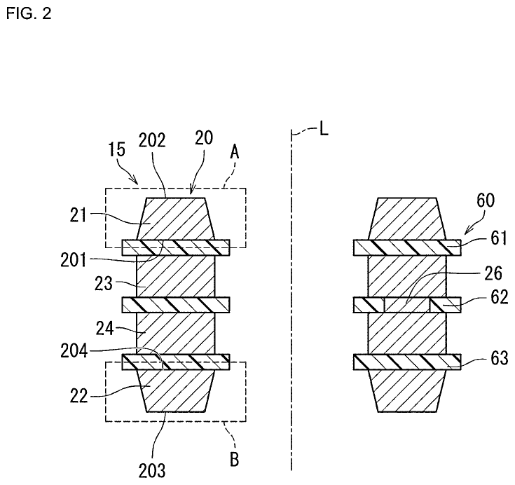

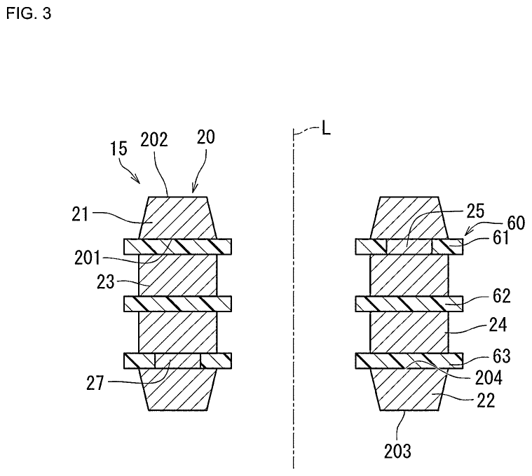

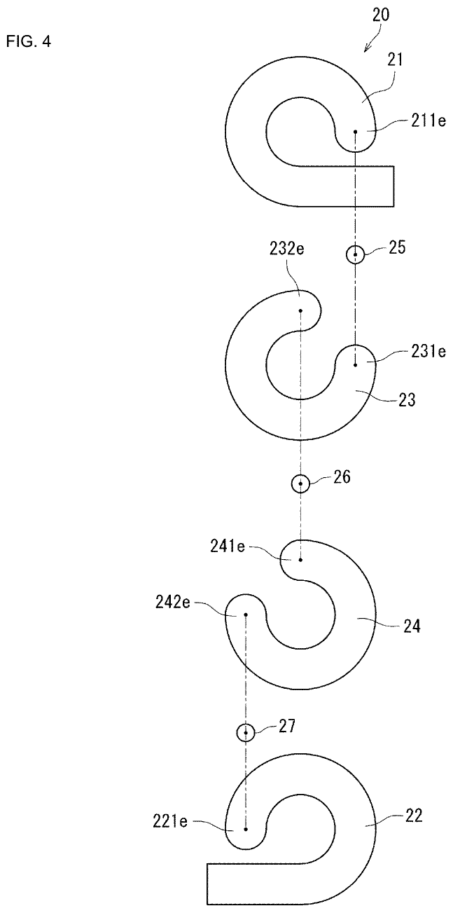

FIG. 1 is a plan view showing a first embodiment of the coil. FIG. 2 is a cross-sectional view taken along line A-A in FIG. 1. FIG. 3 is a cross-sectional view taken along line B-B in FIG. 1. FIG. 4 is an exploded plan view of a coil wire.

As shown in FIGS. 1, 2, 3, and 4, the coil 15 includes a coil wire 20 spirally wound along an axis L and an insulator 60.

In the cross section including the axis L, the coil wire 20 includes a first wiring portion 21, a second wiring portion 22, a third wiring portion 23, and a fourth wiring portion 24 which are arrayed along the axis L, a first connection conductor layer 25 that connects the first wiring portion 21 and the third wiring portion 23 which are adjacent to each other in the direction of the axis L, a second connection conductor layer 26 that connects the third wiring portion 23 and the fourth wiring portion 24 which are adjacent to each other in the direction of the axis L, and a third connection conductor layer 27 that connects the second wiring portion 22 and the fourth wiring portion 24 which are adjacent to each other in the direction of the axis L. The coil 15 can increase the number of turns of the coil 15 by providing the third wiring portion 23 and the fourth wiring portion 24, in addition to the first wiring portion 21 and the second wiring portion 22.

The first wiring portion 21 is disposed in one outermost side portion in the direction of the axis L, and the second wiring portion 22 is disposed in the other outermost side portion in the direction of the axis L. The third wiring portion 23 is disposed between the first wiring portion 21 and the second wiring portion 22. The fourth wiring portion 24 is disposed between the second wiring portion 22 and the third wiring portion 23. In the present embodiment, one side in the direction of the axis L is referred to as an upper side in FIGS. 2 and 3, and the other side in the direction of the axis L is referred to as a lower side in FIGS. 2 and 3.

In other words, the first wiring portion 21, the third wiring portion 23, the fourth wiring portion 24, and the second wiring portion 22 are disposed downward from above in this order. Each of the first wiring portion 21, the second wiring portion 22, the third wiring portion 23, and the fourth wiring portion 24 is a coil conductor layer that extends along a plane orthogonal to the axis L. Each of the first wiring portion 21, the second wiring portion 22, the third wiring portion 23, and the fourth wiring portion 24 has a spiral shape which is smaller than one turn.

Each of the first connection conductor layer 25, the second connection conductor layer 26, and the third connection conductor layer 27 extends along the axis L. Each of the first connection conductor layer 25, the second connection conductor layer 26, and the third connection conductor layer 27 is formed in a disk shape.

As shown in FIG. 4, one end 211e of the first wiring portion 21 and one end 231e of the third wiring portion 23 are connected in series with the first connection conductor layer 25 interposed therebetween. The other end 232e of the third wiring portion 23 and one end 241e of the fourth wiring portion 24 are connected in series with the second connection conductor layer 26 interposed therebetween. The other end 242e of the fourth wiring portion 24 and one end 221e of the second wiring portion 22 are connected in series with the third connection conductor layer 27 interposed therebetween. The first wiring portion 21, the second wiring portion 22, the third wiring portion 23, and the fourth wiring portion 24 are electrically connected in series.

Each shape of the third wiring portion 23 and the fourth wiring portion is not particularly limited. In the present embodiment, in the cross section including the axis L, the shape of the third wiring portion 23 is a rectangular shape including two sides facing each other in the direction of the axis L and two sides facing each other in a direction orthogonal to the direction of the axis L. In addition, in the cross section including the axis L, the shape of the fourth wiring portion 24 is a rectangular shape including two sides facing each other in the direction of the axis L and two sides facing each other in the direction orthogonal to the direction of the axis L.

The coil 15 further includes an insulator 60 that covers at least a portion of the coil wire 20. In FIG. 1, for convenience, the insulator 60 is omitted. For example, the insulator 60 is formed of a composite material of a non-magnetic inorganic material and an organic material, or only the organic material. For example, the organic material is formed of an epoxy resin, an acrylic resin, a phenol resin, a polyimide resin, a liquid crystal polymer, or a combination thereof. For example, the non-magnetic inorganic material is formed of a filler such as silica.

The insulator 60 may be a sintered body such as glass and alumina, or a thin film such as a silicon oxide film, a silicon nitride film, and a silicon oxynitride film. In addition, the insulator 60 may be a magnetic body instead of a non-magnetic body.

The insulator 60 includes a first insulation layer 61, a second insulation layer 62, and a third insulation layer 63. The first insulation layer 61 is provided between the first wiring portion 21 and the third wiring portion 23. The second insulation layer 62 is provided between the third wiring portion 23 and the fourth wiring portion 24. The third insulation layer 63 is provided between the second wiring portion 22 and the fourth wiring portion 24. The first connection conductor layer 25 penetrates the first insulation layer 61. The second connection conductor layer 26 penetrates the second insulation layer 62. The third connection conductor layer 27 penetrates the third insulation layer 63.

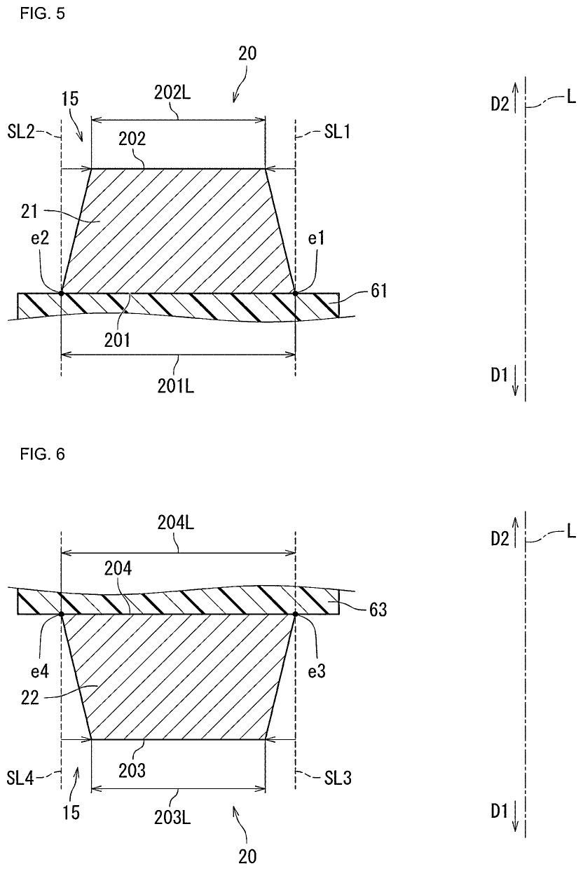

FIG. 5 is an enlarged view of an A portion in FIG. 2. As shown in FIG. 5, the first wiring portion 21 includes a first end surface 201 located on a side in a first direction D1 from the first wiring portion 21 toward the second wiring portion 22 which is the direction of the axis L, and a second end surface 202 located on a side in a second direction D2 which is a direction opposite to the first direction D1. The first end surface 201 includes a first end e1 located in an inner side portion in the radial direction of the coil wire 20. The second end surface 202 is located in an outer side portion in the radial direction of the coil wire 20 with respect to a straight line SL1 passing through the first end e1 and parallel to the direction of the axis L.

The shapes of the first end surface 201 and the second end surface 202 are not particularly limited as long as the second end surface 202 is present at the above-described position. In the present embodiment, in the cross section including the axis L, the shapes of the first end surface 201 and the second end surface 202 are linear.

In the cross section including the axis L, the shape of the side surface of the first wiring portion 21 is not particularly limited as long as the second end surface 202 is present at the above-described position. In the present embodiment, the shape of the side surface in the inner side portion in the radial direction of the coil wire 20 in the first wiring portion 21 is the linear shape extending in a direction away from the axis L as the shape faces the second direction D2. However, the shape of the above-described side surface of the first wiring portion 21 is not limited thereto. For example, the shape may be a recessed curve surface recessed inward of the first wiring portion 21, may be a protruding curve surface protruding outward, or any combination of the recessed curve surface, the protruding curve surface, and a straight line. From a viewpoint of more effectively suppressing the hindrance of the magnetic flux generated by the coil 15, it is preferable that the shape of the above-described side surface of the first wiring portion 21 is the protruding curve surface.

In addition, the shape of the side surface in the outer side portion in the radial direction of the coil wire 20 in the first wiring portion 21 is not particularly limited as long as the second end surface 202 is present at the above-described position, as in the shape of the side surface in the inner side portion in the radial direction. For example, the shape of the side surface in the outer side portion in the radial direction of the first wiring portion 21 may be the recessed curve surface recessed inward of the first wiring portion 21, may be the protruding curve surface protruding outward, or may be any combination of the recessed curve surface, the protruding curve surface, and the straight line. In the present embodiment, the shape of the side surface in the outer side portion in the radial direction of the first wiring portion 21 is the linear shape extending in the direction away from the axis L as the shape faces the first direction D1. That is, in the present embodiment, in the cross section including the axis L, the shape of the first wiring portion 21 is a trapezoidal shape.

According to the coil 15, in the cross section including the axis L, the second end surface 202 is located in the outer side portion in the radial direction of the coil wire 20 with respect to the straight line SL1 passing through the first end e1 and parallel to the direction of the axis L. Therefore, a volume of the coil wire portion present in the path of the magnetic flux generated from the coil 15 can be reduced. In this manner, it is possible to suppress a possibility that the magnetic flux is hindered by the coil wire 20, and it is possible to improve the coil characteristics, compared to the flat coil in the related art. As a result, compared to the flat coil in the related art, for example, even when the size of the coil is reduced by reducing the coil diameter, the coil characteristics equal to those in the related art can be achieved. Therefore, it is possible to achieve both the size reduction and the coil characteristics.

Preferably, as shown in FIG. 5, in the cross section including the axis L, the first end surface 201 includes a second end e2 located in the outer side portion in the radial direction of the coil wire 20, and the second end surface 202 is located in the inner side portion in the radial direction of the coil wire 20 with respect to a straight line SL2 passing through the second end e2 and parallel to the direction of the axis L. According to this configuration, it is possible to further suppress the possibility that the magnetic flux is hindered by the coil wire 20, and it is possible to further improve the coil characteristics, compared to the flat coil in the related art. As a result, it is possible to more effectively achieve both size reduction and the coil characteristics.

Preferably, in the cross section including the axis L, a length 202L of the second end surface 202 is shorter than a length 201L of the first end surface 201. Here, even in the same wiring portion, in some cases, the shapes of the end surfaces of the first end surface 201 and the second end surface 202 are not linear in the cross section including the axis L. In this case, in measuring the above-described lengths 201L and 202L, the length of an imaginary line that linearly connects the first end and the second end of the end surface of a measurement target is measured in the cross section including the axis L.

According to the above-described configuration, it is possible to more effectively suppress the possibility that the magnetic flux is hindered by the coil wire 20, and it is possible to further improve the coil characteristics, compared to the flat coil in the related art. As a result, even when the size of the coil is further reduced compared to the flat coil in the related art, the coil characteristics equal to those in the related art can be achieved. Therefore, it is possible to more easily achieve both the size reduction and the coil characteristics.

FIG. 6 is an enlarged view of a B portion in FIG. 2. As shown in FIG. 6, preferably, in the cross section including the axis L, the second wiring portion 22 includes a third end surface 203 located on a side in the first direction D1 and a fourth end surface 204 located on a side in the second direction D2. The fourth end surface 204 includes a third end e3 located in the inner side portion in the radial direction of the coil wire 20. The third end surface 203 is located in the outer side portion in the radial direction of the coil wire 20 with respect to a straight line SL3 passing through the third end e3 and parallel to the direction of the axis L.

According to the above-described configuration, even when the size of the coil 15 is reduced, the coil characteristics equal to those of the coil in the related art can be more easily achieved. Therefore, it is possible to more easily achieve both the size reduction and the coil characteristics.

In the present embodiment, the shape of the side surface in the inner side portion in the radial direction of the coil wire 20 in the second wiring portion 22 is the linear shape extending in the direction away from the axis L as the shape faces the first direction D1. However, the shape of the above-described side surface of the second wiring portion 22 is not limited thereto. For example, the shape may be the recessed curve surface recessed inward of the second wiring portion 22, the protruding curve surface protruding outward, or any combination of the recessed curve surface, the protruding curve surface, and the straight line. From a viewpoint of more effectively suppressing the hindrance of the magnetic flux generated by the coil 15, it is preferable that the shape of the above-described side surface of the second wiring portion 22 is the protruding curve surface.

Preferably, in the cross section including the axis L, the fourth end surface 204 includes a fourth end e4 located in the outer side portion in the radial direction of the coil wire 20, and the third end surface 203 is located in the inner side portion in the radial direction of the coil wire 20 with respect to a straight line SL4 passing through the fourth end e4 and parallel to the direction of the axis L.

According to the above-described configuration, it is possible to further suppress the possibility that the magnetic flux is hindered by the coil wire 20, and it is possible to further improve the coil characteristics, compared to the flat coil in the related art. As a result, it is possible to more effectively achieve both size reduction and the coil characteristics.

In addition, the shape of the side surface in the outer side portion in the radial direction of the coil wire 20 in the second wiring portion 22 is not particularly limited. As in the shape of the side surface in the inner side portion in the radial direction, the shape is not particularly limited. For example, the shape of the side surface in the outer side portion in the radial direction of the second wiring portion 22 may be the recessed curve surface recessed inward of the second wiring portion 22, a protruding curve surface protruding outward, or any combination of the recessed curve surface, the protruding curve surface, and the straight line. In the present embodiment, the shape of the side surface in the outer side portion in the radial direction of the second wiring portion 22 is the linear shape extending in the direction away from the axis L as the shape faces the second direction D2. That is, in the present embodiment, in the cross section including the axis L, the shape of the second wiring portion 22 is a trapezoidal shape.

Preferably, in the cross section including the axis L, a length 203L of the third end surface 203 is shorter than a length 204L of the fourth end surface 204. Here, even in the same wiring portion, in some cases, the shapes of the third end surface 203 and the fourth end surface 204 are not linear in the cross section including the axis L. In this case, in measuring the above-described lengths 203L and 204L, the length of an imaginary line that linearly connects the first end and the second end of the end surface of a measurement target is measured in the cross section including the axis L.

According to the above-described configuration, it is possible to more effectively suppress the possibility that the magnetic flux is hindered by the coil wire 20, and it is possible to further improve the coil characteristics, compared to the flat coil in the related art. As a result, even when the size of the coil is further reduced compared to the coil in the related art, the coil characteristics equal to those in the related art can be achieved. Therefore, it is possible to more easily achieve both the size reduction and the coil characteristics.

Preferably, in the cross section including the axis L, the length 202L of the second end surface 202 is equal to or more than 80% and equal to or less than 95% of the length 201L of the first end surface 201.

According to the above-described configuration, it is possible to more easily achieve both the size reduction and the coil characteristics. Specifically, the length 202L of the second end surface 202 is equal to or more than 80% of the length 201L of the first end surface 201. In this manner, a volume of the coil wire 20 can be increased, and the coil characteristics can be improved. In addition, the length 202L of the second end surface 202 is equal to or less than 95% of the length 201L of the first end surface 201. In this manner, it is possible to further suppress the possibility that the magnetic flux is hindered by the coil wire 20.

Preferably, in the cross section including the axis L, the length 203L of the third end surface 203 is equal to or more than 80% and equal to or less than 95% of the length 204L of the fourth end surface 204.

According to the above-described configuration, it is possible to more easily achieve both the size reduction and the coil characteristics. Specifically, the length 203L of the third end surface 203 is equal to or more than 80% of the length 204L of the fourth end surface 204. In this manner, the volume of the coil wire 20 can be increased, and the coil characteristics can be improved. In addition, the length 203L of the third end surface 203 is equal to or less than 95% of the length 204L of the fourth end surface 204. In this manner, it is possible to further suppress the possibility that the magnetic flux is hindered by the coil wire 20.

### (Manufacturing Method)

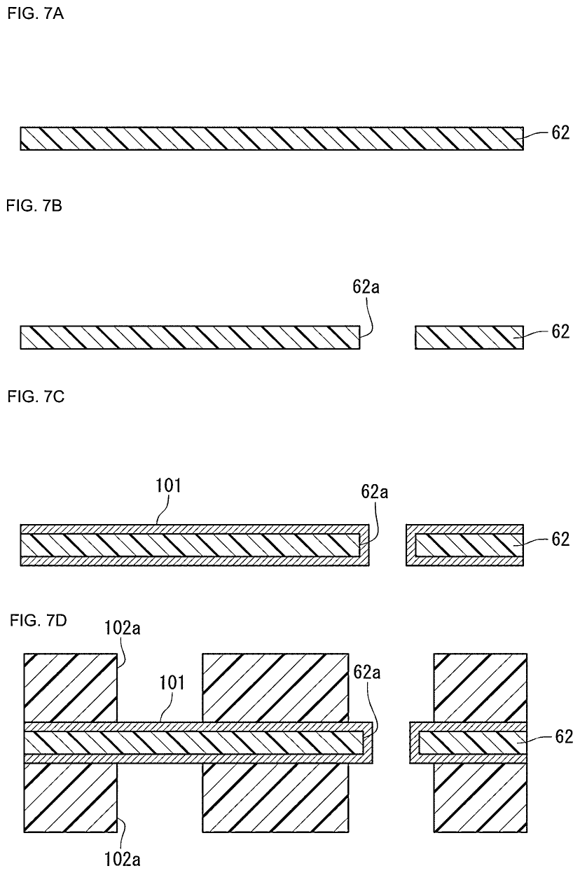

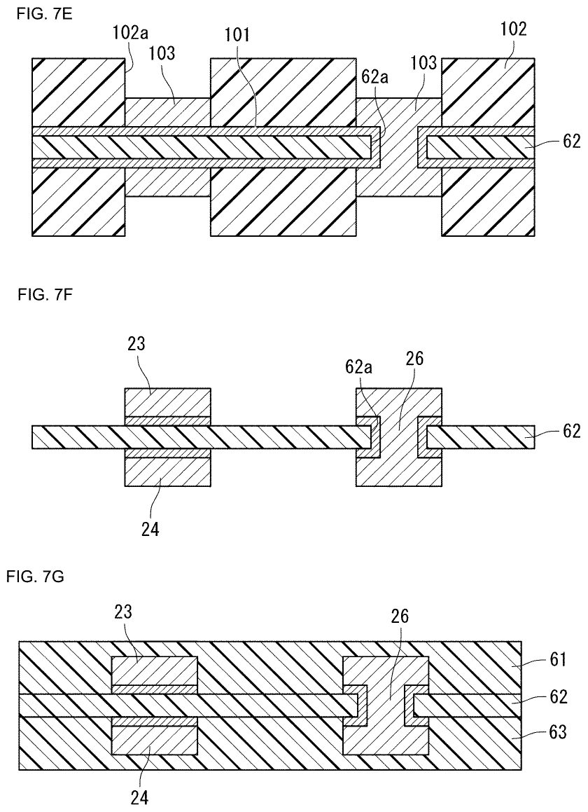

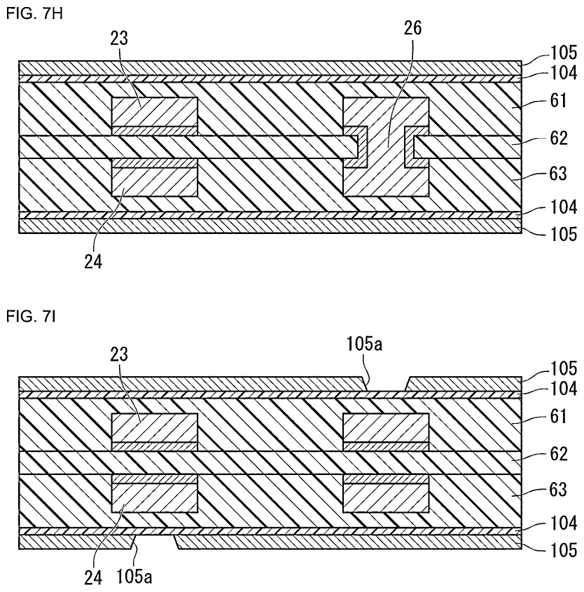

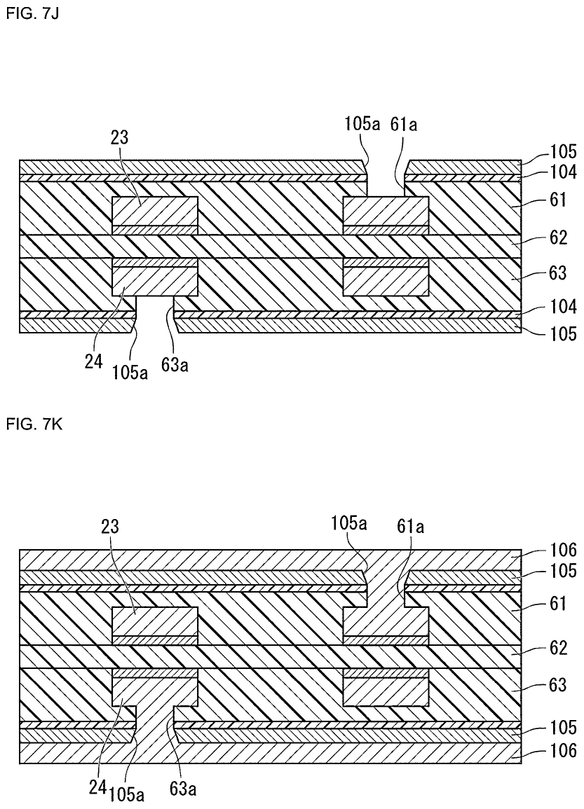

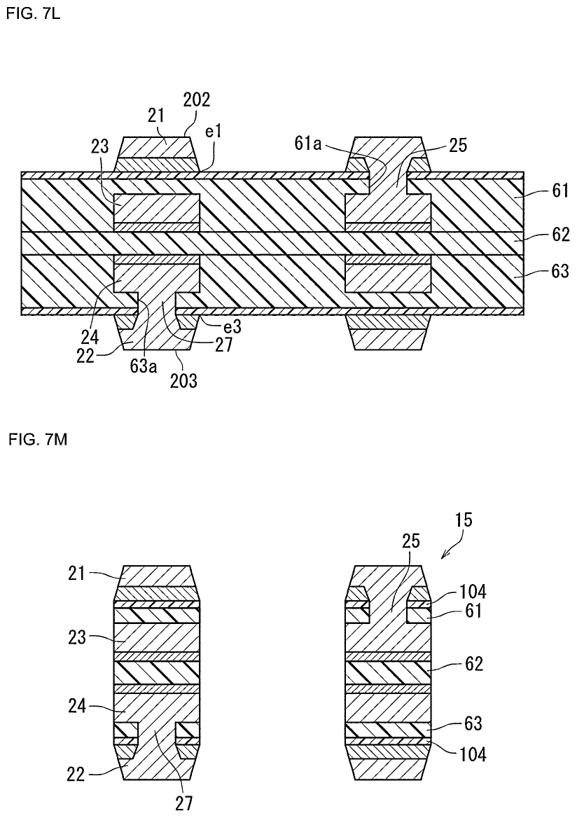

Next, a manufacturing method for the coil 15 will be described. FIGS. 7A to 7H correspond to a cross section taken along line A-A in FIG. 1. FIGS. 7I to 7M correspond to a cross section taken along line B-B in FIG. 1.

As shown in FIG. 7A, the second insulation layer 62 is prepared, and as shown in FIG. 7B, a portion of the second insulation layer 62 is removed by laser processing to form a through-hole 62a.

As shown in FIG. 7C, a seed layer 101 is formed on a front surface of the second insulation layer 62 through sputtering. The seed layer 101 is formed of Cu/Ti. The seed layer 101 is also formed on an inner surface of the through-hole 62a.

As shown in FIG. 7D, coil pattern portions 102a are formed on both surfaces of the second insulation layer 62 by using a photoresist 102. As shown in FIG. 7E, a metal film 103 is formed on the through-hole 62a and the coil pattern portion 102a through electrolytic plating. The metal film 103 is formed of Cu.

As shown in FIG. 7F, the photoresist 102 is peeled off, and the exposed seed layer 101 is etched. The third wiring portion 23 is formed on the upper surface of the second insulation layer 62 by the seed layer 101 and the metal film 103, the fourth wiring portion 24 is formed on the lower surface of the second insulation layer 62, and the second connection conductor layer 26 is formed in the through-hole 62a of the second insulation layer 62.

As shown in FIG. 7G, the first insulation layer 61 is formed on the upper surface of the second insulation layer 62 to cover the third wiring portion 23, and the third insulation layer 63 is formed on the lower surface of the second insulation layer 62 to cover the fourth wiring portion 24. As shown in FIG. 7H, a metal foil 105 is attached to the upper surface of the first insulation layer 61 and the lower surface of the third insulation layer 63 via an adhesive layer 104 interposed therebetween. The metal foil 105 is formed of Cu.

As shown in FIG. 7I, a via pattern portion is formed by using a photoresist (not shown), and a via opening portion 105a is formed in the upper and lower metal foils 105 through etching. As shown in FIG. 7J, a position overlapping with the upper side via opening portion 105a in the first insulation layer 61 and the adhesive layer 104 is removed through laser processing to form a via opening portion 61a. In addition, a position overlapping the lower side via opening portion 105a in the third insulation layer 63 and the adhesive layer 104 is removed through laser processing to form a via opening portion 63a.

As shown in FIG. 7K, a metal film 106 is formed on the via opening portions 61a, 63a, and 105a through electrodeless plating and electrolytic plating. In this case, the electroless coating film may be used as a power supply film of the electrodeposited coating film. The metal film 106 is formed of Cu.

As shown in FIG. 7L, a coil pattern portion is formed by using a photoresist (not shown), and the metal foil 105 and the metal film 106 are etched. The first wiring portion 21 is formed on the upper surface of the first insulation layer 61 by the metal foil 105 and the metal film 106, the second wiring portion 22 is formed on the lower surface of the third insulation layer 63, the first connection conductor layer 25 is formed in the via opening portion 61a of the first insulation layer 61, and the third connection conductor layer 27 is formed in the via opening portion 63a of the third insulation layer 63. In this case, etching conditions are controlled such that the second end surface 202 of the first wiring portion 21 is located in the outer side portion in the radial direction of the coil wire 20 with respect to a straight line passing through the first end e1 and parallel to the direction of the axis L. In addition, the third end surface 203 of the second wiring portion 22 is controlled to be located in the outer side portion in the radial direction of the coil wire 20 with respect to a straight line passing through the third end e3 and parallel to the direction of the axis L. In addition, the second end surface 202 of the first wiring portion 21 is controlled to be located in the inner side portion in the radial direction of the coil wire 20 with respect to a straight line passing through the second end e2 and parallel to the direction of the axis L. In addition, the third end surface 203 of the second wiring portion 22 is controlled to be located in the inner side portion in the radial direction of the coil wire 20 with respect to a straight line passing through the fourth end e4 and parallel to the direction of the axis L.

As shown in FIG. 7M, the first insulation layer 61, the second insulation layer 62, the third insulation layer 63, and the adhesive layer 104 which are located in the inner magnetic path and the outer magnetic path, are removed through laser processing to form the coil 15. In this case, the coil 15 may be individually processed, or a plurality of the coils 15 may be integrally connected.

### Second Embodiment

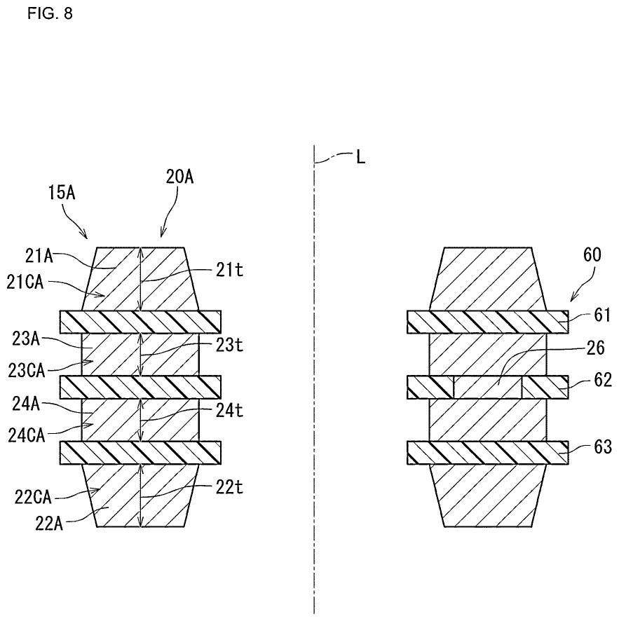

FIG. 8 is a cross-sectional view showing a second embodiment of the coil. FIG. 8 corresponds to FIG. 2. The second embodiment is different from the first embodiment in a the cross-sectional shape of the coil wire. The different configuration will be described below. Other configurations are the same configurations as those of the first embodiment, and the same reference numerals as those of the first embodiment will be assigned, and description thereof will be omitted.

As shown in FIG. 8, in the cross section including the axis L, a thickness 21t of the first wiring portion 21A is thicker than a thickness 23t of the third wiring portion 23A. Here, the thickness 21t and the thickness 23t refer to a maximum thickness in a direction parallel to the axis L. According to this configuration, a volume of the first wiring portion 21A can be equal to or larger than a volume of the third wiring portion 23A. Therefore, electrical resistance of the coil wire 20A can be reduced.

Preferably, in the cross section including the axis L, a thickness 22t of the second wiring portion 22A is thicker than a thickness 23t of the third wiring portion 23A. Here, the thickness 22t refers to the maximum thickness in the direction parallel to the axis L. According to this configuration, the volume of the second wiring portion 22A can be equal to or larger than the volume of the third wiring portion 23A. Therefore, the electrical resistance of the coil wire 20A can be reduced.

Preferably, in the cross section including the axis L, the thickness 21t of the first wiring portion 21A is thicker than a thickness 24t of the fourth wiring portion 24A. Here, the thickness 24t refers to the maximum thickness in the direction parallel to the axis L. According to this configuration, the volume of the first wiring portion 21A can be equal to or larger than the volume of the fourth wiring portion 24A. Therefore, the electrical resistance of the coil wire 20A can be reduced.

Preferably, in the cross section including the axis L, the thickness 22t of the second wiring portion 22A is thicker than the thickness 24t of the fourth wiring portion 24A. According to this configuration, the volume of the second wiring portion 22A can be equal to or larger than the volume of the fourth wiring portion 24A. Therefore, the electrical resistance of the coil wire 20A can be reduced.

Preferably, in the cross section including the axis L, a cross-sectional area 21CA of the first wiring portion 21A is equal to or more than 0.8 times and equal to or less than 1.2 times a cross-sectional area 23CA of the third wiring portion 23A. According to this configuration, the cross-sectional area 21CA of the first wiring portion 21A can be equal to the cross-sectional area 23CA of the third wiring portion 23A. Therefore, the electrical resistance can be constant over the entire length of the coil wire 20A.

Preferably, in the cross section including the axis L, a cross-sectional area 22CA of the second wiring portion 22A is equal to or more than 0.8 times and equal to or less than 1.2 times the cross-sectional area 23CA of the third wiring portion 23A. According to this configuration, the cross-sectional area 22CA of the second wiring portion 22A can be equal to the cross-sectional area 23CA of the third wiring portion 23A. Therefore, the electrical resistance can be constant over the entire length of the coil wire 20A.

Preferably, in the cross section including the axis L, a cross-sectional area 21CA of the first wiring portion 21A is equal to or more than 0.8 times and equal to or less than 1.2 times a cross-sectional area 24CA of the fourth wiring portion 24A. According to this configuration, the cross-sectional area 21CA of the first wiring portion 21A can be equal to the cross-sectional area 24CA of the fourth wiring portion 24A. Therefore, the electrical resistance can be constant over the entire length of the coil wire 20A.

Preferably, in the cross section including the axis L, a cross-sectional area 22CA of the second wiring portion 22A is equal to or more than 0.8 times and equal to or less than 1.2 times a cross-sectional area 24CA of the fourth wiring portion 24A. According to this configuration, the cross-sectional area 22CA of the second wiring portion 22A can be equal to the cross-sectional area 24CA of the fourth wiring portion 24A. Therefore, the electrical resistance can be constant over the entire length of the coil wire 20A.

### Third Embodiment

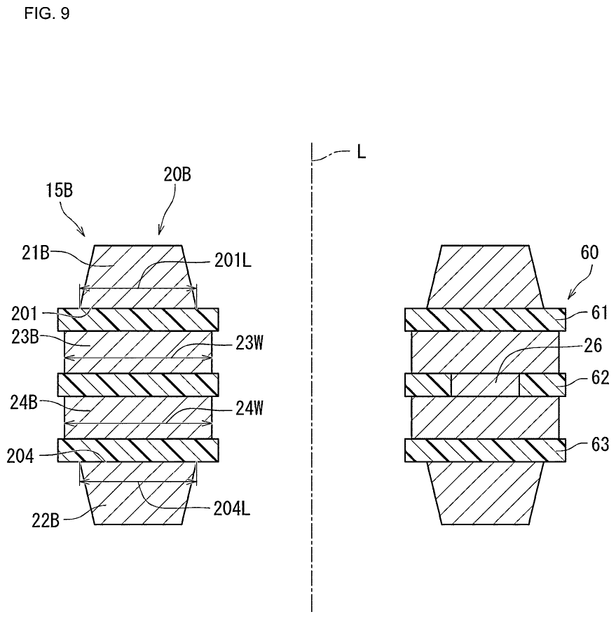

FIG. 9 is a cross-sectional view showing a third embodiment of the coil. FIG. 9 corresponds to FIG. 2. The third embodiment is different from the first embodiment in a cross-sectional shape of the coil wire. The different configuration will be described below. Other configurations are the same configurations as those of the first embodiment, and the same reference numerals as those of the first embodiment will be assigned, and description thereof will be omitted.

As shown in FIG. 9, in the cross section including the axis L, the length 201L of the first end surface 201 is equal to a maximum width 23W of the third wiring portion 23B in the radial direction of the coil wire 20B, or is shorter than the maximum width 23W of the third wiring portion 23B. In the present embodiment, the length 201L is shorter than the maximum width 23W of the third wiring portion 23B. According to this configuration, in the cross section including the axis L, the volume of the coil wire portion present in the path of the magnetic flux generated from the coil 15B can be reduced, compared to when the length 201L of the first end surface 201 is longer than the maximum width 23W of the third wiring portion 23B in the radial direction of the coil wire 20B. In this manner, even when the coil wire 20B includes the third wiring portion 23B, it is possible to achieve both the size reduction and the coil characteristics.

Preferably, in the cross section including the axis L, the length 204L of the fourth end surface 204 is equal to the maximum width 23W of the third wiring portion 23B in the radial direction of the coil wire 20B, or is shorter than the maximum width 23W of the third wiring portion 23B. In the present embodiment, the length 204L is shorter than the maximum width 23W of the third wiring portion 23B. According to this configuration, in the cross section including the axis L, the volume of the coil wire portion present in the path of the magnetic flux generated from the coil 15B can be reduced, compared to when the length 204L of the fourth end surface 204 is longer than the maximum width 23W of the third wiring portion 23B in the radial direction of the coil wire 20B. In this manner, even when the coil wire 20B includes the third wiring portion 23B, it is possible to achieve both the size reduction and the coil characteristics.

Preferably, in the cross section including the axis L, the length 201L of the first end surface 201 is equal to a maximum width 24W of the fourth wiring portion 24B in the radial direction of the coil wire 20B, or is shorter than the maximum width 24W of the fourth wiring portion 24B. In the present embodiment, the length 201L is shorter than the maximum width 24W of the fourth wiring portion 24B. In this manner, in the cross section including the axis L, the volume of the coil wire portion present in the path of the magnetic flux generated from the coil 15B can be reduced, compared to when the length 201L of the first end surface 201 is longer than the maximum width 24W of the fourth wiring portion 24B in the radial direction of the coil wire 20B. In this manner, when the coil wire 20B includes the fourth wiring portion 24B, it is possible to achieve both the size reduction and the coil characteristics.

Preferably, in the cross section including the axis L, the length 204L of the fourth end surface 204 is equal to the maximum width 24W of the fourth wiring portion 24B in the radial direction of the coil wire 20B, or is shorter than the maximum width 24W of the fourth wiring portion 24B. In the present embodiment, the length 204L is shorter than the maximum width 24W of the fourth wiring portion 24B. In this manner, in the cross section including the axis L, the volume of the coil wire portion present in the path of the magnetic flux generated from the coil 15B can be reduced, compared to when the length 204L of the fourth end surface 204 is longer than the maximum width 24W of the fourth wiring portion 24B in the radial direction of the coil wire 20B. In this manner, when the coil wire 20B includes the fourth wiring portion 24B, it is possible to achieve both the size reduction and the coil characteristics.

### Fourth Embodiment

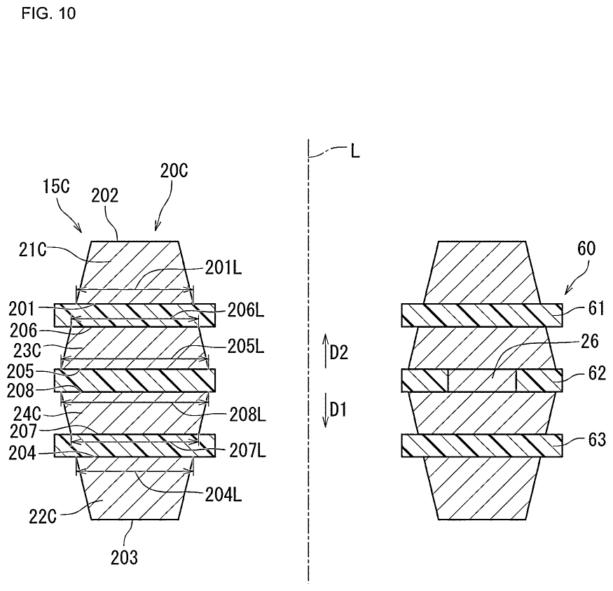

FIG. 10 is a cross-sectional view showing a fourth embodiment of the coil. FIG. 10 corresponds to FIG. 2. The fourth embodiment is different from the first embodiment in a shape of the coil wire. The different configuration will be described below. Other configurations are the same configurations as those of the first embodiment, and the same reference numerals as those of the first embodiment will be assigned, and description thereof will be omitted.

As shown in FIG. 10, in the cross section including the axis L, the third wiring portion 23C includes a fifth end surface 205 located on a side in the first direction D1 and a sixth end surface 206 located on a side in the second direction D2. A length 206L of the sixth end surface 206 is shorter than a length 205L of the fifth end surface 205, and is equal to the length 201L of the first end surface 201, or is longer than the length 201L of the first end surface 201. In the present embodiment, the length 206L is longer than the length 201L. That is, in the present embodiment, in the cross section including the axis L, the shape of the third wiring portion 23C is a trapezoidal shape. In this manner, it is possible to effectively suppress the possibility that the magnetic flux is hindered by the coil wire 20C. Therefore, it is possible to more easily achieve both the size reduction and the coil characteristics.

Preferably, in the cross section including the axis L, the fourth wiring portion 24C includes a seventh end surface 207 located on a side in the first direction D1 and an eighth end surface 208 located on a side in the second direction D2. A length 207L of the seventh end surface 207 is shorter than the length of the eighth end surface 208L, and is equal to the length 204L of the fourth end surface 204, or is longer than the length 204L of the fourth end surface 204. In the present embodiment, the length 207L is longer than the length 204L. That is, in the present embodiment, in the cross section including the axis L, the shape of the fourth wiring portion 24C is a trapezoidal shape. In addition, in the cross section including the axis L, the overall shape of the first to fourth wiring portions 21C to 24C is an elliptical shape. According to this configuration, it is possible to more effectively suppress the possibility that the magnetic flux is hindered by the coil wire 20C. Therefore, it is possible to more easily achieve both the size reduction and the coil characteristics.

### Fifth Embodiment

### (Configuration)

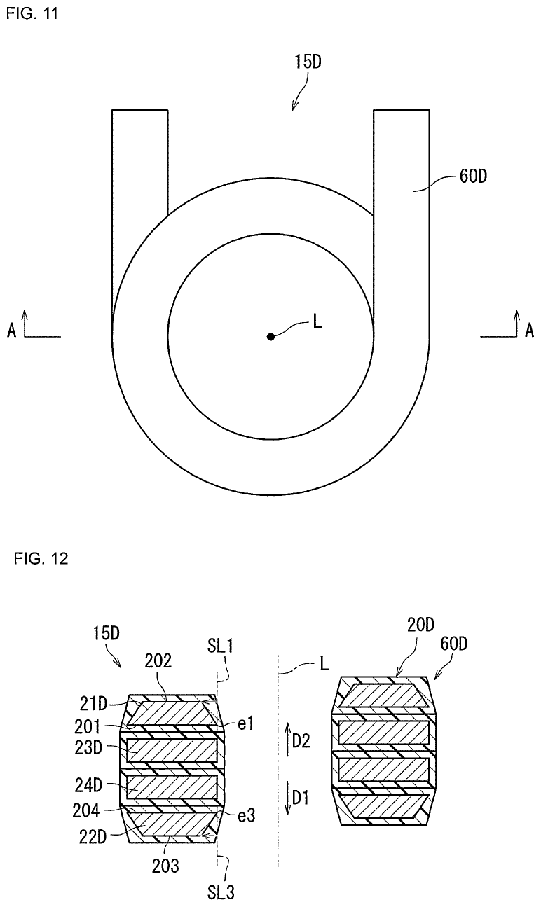

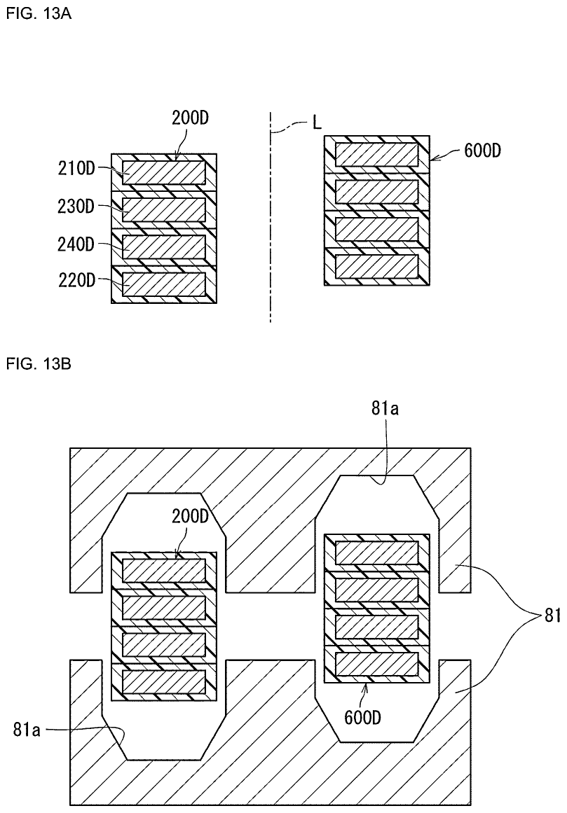

FIG. 11 is a plan view showing a fifth embodiment of the coil. FIG. 12 is a cross-sectional view taken along line A-A in FIG. 11. The fifth embodiment is different from the first embodiment in configurations of the coil wire and the insulator. The different configuration will be described below. Other configurations are the same configurations as those of the first embodiment, and the same reference numerals as those of the first embodiment will be assigned, and description thereof will be omitted.

As shown in FIGS. 11 and 12, a coil 15D includes a coil wire 20D spirally wound along the axis L, and an insulator 60D that covers at least a portion of the coil wire 20D. In the present embodiment, the insulator 60D covers the entire outer surface of the coil wire 20D.

The coil wire 20D is formed by spirally winding a flat plate-shaped (flat) conductor along the axis L. That is, the coil wire 20D is formed to continuously proceed along the axis L. The coil wire 20D is formed in a cylindrical shape, and the axis L is also referred to as a center of the cylinder. The coil wire 20D is formed of a metal conductor such as a copper plate.

As shown in FIG. 12, in the cross section including the axis L, the coil wire 20 includes a first wiring portion 21D, a second wiring portion 22D, a third wiring portion 23D, and a fourth wiring portion 24D which are arrayed along the axis L.

The first wiring portion 21D is disposed in one outermost side portion in the direction of the axis L, and the second wiring portion 22D is disposed in the other outermost side portion in the direction of the axis L. The third wiring portion 23D is disposed between the first wiring portion 21D and the second wiring portion 22D. The fourth wiring portion 24D is disposed between the second wiring portion 22D and the third wiring portion 23D. In the present embodiment, one side in the direction of the axis L is referred to as the upper side in FIG. 12, and the other side in the direction of the axis L is referred to as the lower side in FIG. 12. In other words, the first wiring portion 21, the third wiring portion 23, the fourth wiring portion 24, and the second wiring portion 22 are disposed downward from above in this order.

The first wiring portion 21D and the third wiring portion 23D form adjacent turns of the coil wire 20D in the direction of the axis L. The third wiring portion 23D and the fourth wiring portion 24D form adjacent turns of the coil wire 20D in the direction of the axis L. The fourth wiring portion 24D and the second wiring portion 22D form adjacent turns of the coil wire 20D in the direction of the axis L.

The first wiring portion 21D includes a first end surface 201 located on a side in the first direction D1 from the first wiring portion 21D toward the second wiring portion 22D which is the direction of the axis L, and a second end surface 202 located on a side in the second direction D2 opposite to the first direction D1. The first end surface 201 includes a first end e1 located in the inner side portion in the radial direction of the coil wire 20D. The second end surface 202 is located in the outer side portion in the radial direction of the coil wire 20D with respect to the straight line SL1 passing through the first end e1 and parallel to the direction of the axis L.

The insulator 60D is an insulation coating film that covers the coil wire 20D. A forming material of the insulator 60D may be the same as that of the first embodiment.

According to the above-described configuration, in the cross section including the axis L, the second end surface 202 is located in the outer side portion in the radial direction of the coil wire 20 with respect to the straight line SL1 passing through the first end e1 and parallel to the direction of the axis L. Therefore, it is possible to reduce the volume of the coil wire portion present in the path of the magnetic flux generated from the coil 15D. In this manner, it is possible to suppress the possibility that the magnetic flux is hindered by the coil wire 20D, and it is possible to improve the coil characteristics, compared to the flat coil in the related art. As a result, even when the size of the coil is reduced compared to the flat coil in the related art, the coil characteristics equal to those in the related art can be achieved. Therefore, it is possible to achieve both the size reduction and the coil characteristics.

Preferably, the second wiring portion 22D includes a third end surface 203 located on a side in the first direction D1 and a fourth end surface 204 located on a side in the second direction D2. The fourth end surface 204 includes a third end e3 located in the inner side portion in the radial direction of the coil wire 20D. The third end surface 203 is located in the outer side portion in the radial direction of the coil wire 20D with respect to the straight line SL3 passing through the third end e3 and parallel to the direction of the axis L. According to this configuration, it is possible to more easily achieve both the size reduction and the coil characteristics.

### (Manufacturing Method)

As an example of a manufacturing method for the coil 15D, for example, as shown in FIG. 13A, a flat coil wire 200D covered with an insulation layer 600D is prepared. As shown in FIG. 13B, the coil 15D shown in FIG. 12 can be manufactured by molding the flat coil wire 200D with a mold 81. An inner surface 81a of the mold 81 has a shape corresponding to a shape of the coil wire 20D.

### Sixth Embodiment

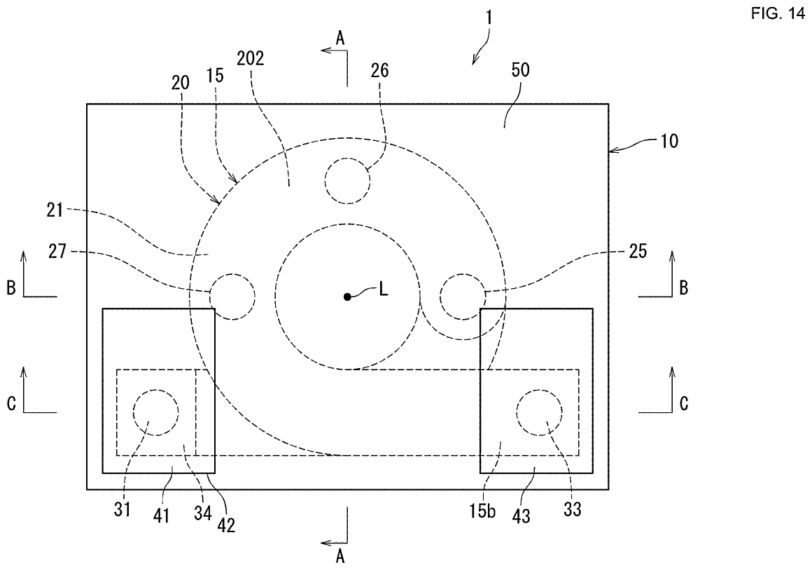

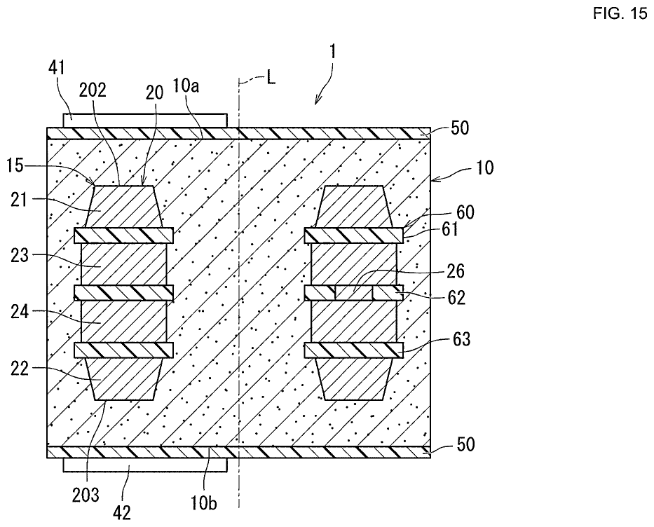

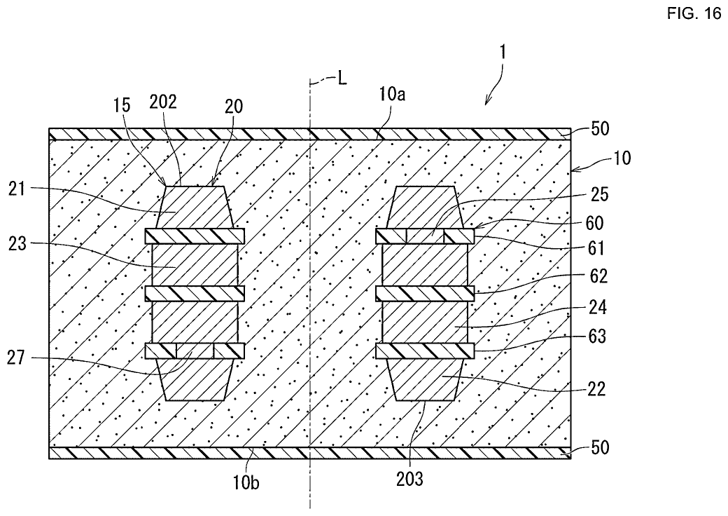

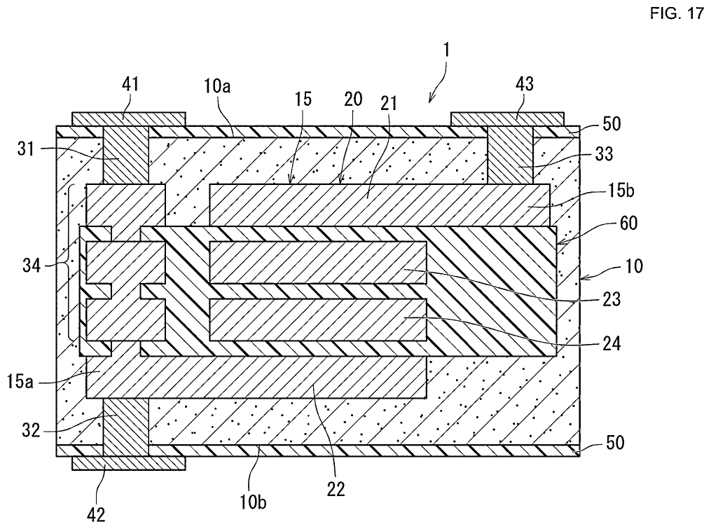

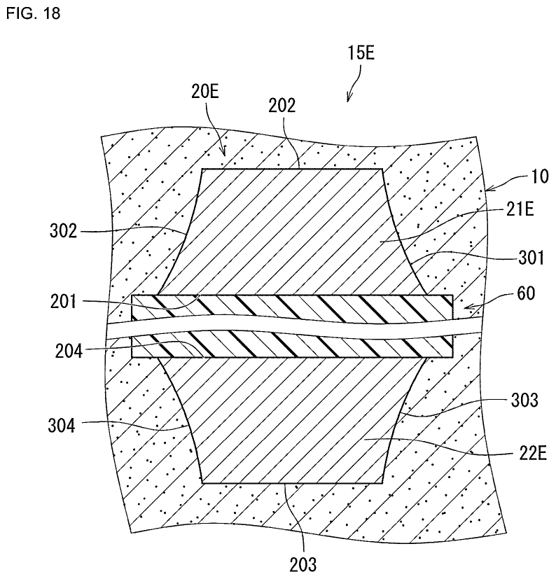

FIG. 14 is a plan view showing an embodiment of an inductor component. FIG. 15 is a cross-sectional view taken along line A-A in FIG. 14. FIG. 16 is a cross-sectional view taken along line B-B in FIG. 14. FIG. 17 is a cross-sectional view taken along line C-C in FIG. 14.

For example, an inductor component 1 is mounted on electronic devices such as a personal computer, a DVD player, a digital camera, a TV, a mobile phone, and car electronics, and for example, is a component having a rectangular parallelepiped shape as a whole. However, the shape of the inductor component 1 is not particularly limited, and may be a columnar shape, a polygonal columnar shape, a frustum shape, or a polygonal frustum shape.

As shown in FIGS. 14, 15, 16, and 17, the inductor component 1 includes an element body 10 including a magnetic material, and a coil 15 disposed in the element body 10. According to this configuration, it is possible to suppress the possibility that the magnetic flux is hindered by the coil wire 20. Therefore, it is possible to obtain the inductor component 1 which achieves both the size reduction and the inductance value.

The inductor component 1 further includes a first external terminal 41, a second external terminal 42, and a third external terminal 43 which are provided on an outer surface of the element body 10 and which are electrically connected to the coil 15, and an insulation film 50 disposed between each portion of the first external terminal 41, the second external terminal 42, and the third external terminal 43 and the outer surface of the element body 10. Here, the position “on the outer surface” includes not only a position (on) directly above a portion in contact with the outer surface but also a position (above) separated from the outer surface, that is, an upper side position with another object on the outer surface interposed therebetween or an upper side position at an interval therebetween.

According to the above-described configuration, the inductor component 1 includes the external terminals 41 to 43. Therefore, when the inductor component 1 is mounted on a mounting substrate (not shown), the inductor component 1 can be easily connected to a wire of the mounting substrate. In addition, the inductor component 1 includes the insulation film 50. Therefore, insulation properties between the external terminal 41 to 43 and the coil 15 are improved. In addition, the insulation film 50 is disposed in an outer side portion of the element body 10. Therefore, the insulation film 50 does not hinder the magnetic flux of the coil 15. In contrast, when the insulation film is provided inside the element body to ensure the insulation properties between the coil and the external terminal, there is a possibility that the insulation film hinders the magnetic flux of the coil.

The outer surface of the element body 10 includes a first surface 10a and a second surface 10b which face each other. The first surface 10a and the second surface 10b are orthogonal to the axis L of the coil 15. In the present embodiment, the first surface 10a is the upper surface, and the second surface 10b is the lower surface.

The element body 10 is formed of a composite material of a metal magnetic powder and an organic material. For example, the metal magnetic powder is formed of an FeSi-based alloy such as FeSiCr, an FeCo-based alloy, an Fe-based alloy such as NiFe, or an amorphous alloy thereof. For example, the organic material is formed of an epoxy resin, an acrylic resin, a phenol resin, a polyimide resin, a liquid crystal polymer, or a combination thereof.

According to the above-described configuration, DC superimposition characteristics can be improved by the metal magnetic powder. In addition, for example, when the inductor component 1 is incorporated into the substrate, the resin elastically absorbs stress applied from the outside to reduce internal stress applied to the metal magnetic powder. In this manner, it is possible to prevent an inductance value from being degraded due to magnetic distortion. In some cases, the element body does not need to include an organic resin such as ferrite or a sintered body of a magnetic powder.

The coil 15 includes a first end portion 15a which is a lowermost end on the second surface 10b side, and a second end portion 15b which is an uppermost end on the first surface 10a side. A second extended wire 32 and a fourth extended wire 34 are connected to the coil wire 20 of the first end portion 15a. A third extended wire 33 is connected to the coil wire 20 of the second end portion 15b. A first extended wire 31 is connected to the fourth extended wire 34.

The fourth extended wire 34 extends from the first end portion 15a toward the first surface 10a side along the axis L. The first extended wire 31 extends from the fourth extended wire 34 toward the first surface 10a side along the axis L, and is exposed from the first surface 10a and the insulation film 50. The second extended wire 32 extends from the first end portion 15a toward the second surface 10b side along the axis L. The second extended wire 32 is exposed from the second surface 10b and the insulation film 50. The third extended wire 33 extends from the second end portion 15b toward the first surface 10a side along the axis L. The third extended wire 33 is exposed from the first surface 10a and the insulation film 50.

The first external terminal 41 is provided on the first surface 10a, and is connected to the first extended wire 31. The insulation film 50 is disposed between a portion of the first external terminal 41 and the first surface 10a. The second external terminal 42 is provided on the second surface 10b, and is connected to the second extended wire 32. The insulation film 50 is disposed between a portion of the second external terminal 42 and the second surface 10b. The third external terminal 43 is provided on the first surface 10a, and is connected to the third extended wire 33. The insulation film 50 is disposed between a portion of the third external terminal 43 and the first surface 10a. Here, the position “on the first surface” includes not only a position (on) directly above a portion in contact with the first surface but also a position (above) separated from the first surface, that is, an upper side position with another object on the first surface interposed therebetween or an upper side position at an interval therebetween. The same applies to the position on the second surface.

The first external terminal 41 and the second external terminal 42 have the same potential. Accordingly, when the inductor component 1 is incorporated into the substrate to form an electronic circuit, the inductor component 1 can be connected to a circuit from both sides of the first surface 10a and the second surface 10b of the inductor component 1, and the size of the electronic circuit can be reduced.

The second external terminal 42 and the second extended wire 32 do not need to be provided, and the first external terminal 41 and the third external terminal 43 may be provided. In addition, the third external terminal 43 may be provided on the second surface 10b instead of the first surface 10a. In addition, the first external terminal 41 and the third external terminal 43 may be brought into contact with the first surface 10a, and the second external terminal 42 may be brought into contact with the second surface 10b without providing the insulation film 50.

### Seventh Embodiment

FIG. 18 is a cross-sectional view showing an inductor component according to an embodiment. FIG. 18 corresponds to FIG. 15, and is a partially enlarged view of the first wiring portion and the second wiring portion. In FIG. 18, for convenience, the third wiring portion and the fourth wiring portion are omitted in the drawing. A seventh embodiment is different from the sixth embodiment in a cross-sectional shape of the coil wire. The different configuration will be described below. Other configurations are the same configurations as those of the sixth embodiment, and the same reference numerals as those of the sixth embodiment will be assigned, and description thereof will be omitted.

As shown in FIG. 18, in the cross section including the axis L, a first wiring portion 21E includes a first side surface 301 and a second side surface 302 which connect the first end surface 201 and the second end surface 202. A second wiring portion 22E includes a third side surface 303 and a fourth side surface 304 which connect the third end surface 203 and the fourth end surface 204. At least one side surface of the first side surface 301, the second side surface 302, the third side surface 303, and the fourth side surface 304 has a recessed shape recessed inward of the first wiring portion 21E or the second wiring portion 22E.

In the present embodiment, in the cross section including the axis L, each side surface of the first side surface 301 and the second side surface 302 is formed in a recessed shape recessed inward of the first wiring portion 21E. Each side surface of the third side surface 303 and the fourth side surface 304 has a recessed shape recessed inward of the second wiring portion 22E. The above-described “recessed shape” is not particularly limited as long as the shape is recessed inward of the first wiring portion 21E or the second wiring portion 22E. In the present embodiment, the above-described “recessed shape” is an arc shape in the cross section including the axis L.

According to the above-described configuration, a contact area between the coil wire 20E and the element body 10 is increased, and close contact between the coil wire 20E and the element body 10 is improved. Therefore, mechanical strength of the inductor component 1 can be improved.

### Eighth Embodiment

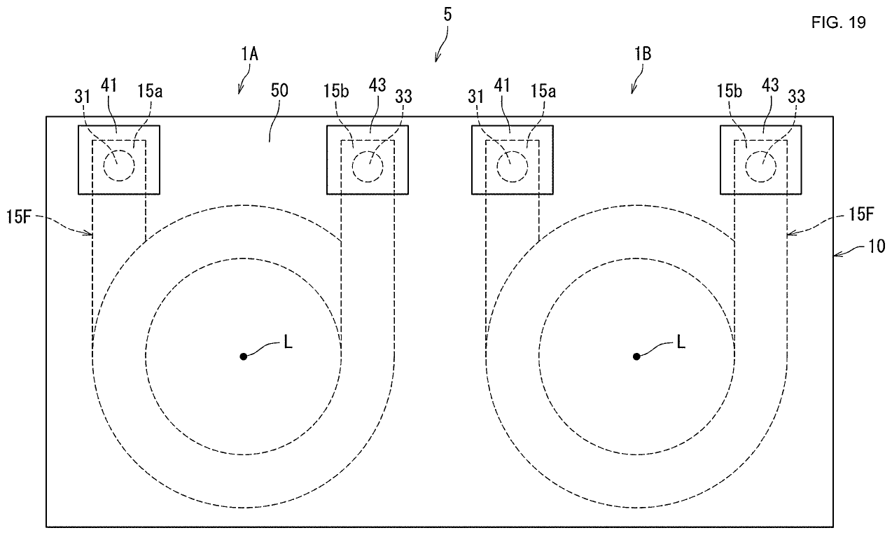

FIG. 19 is a plan view showing an embodiment of the inductor array. As shown in FIG. 19, the inductor array 5 includes a first inductor component 1A and a second inductor component 1B. The first inductor component 1A and the second inductor component 1B have the same configurations as the inductor component 1 according to the sixth embodiment, except for the disposition of the first end portion and the second end portion of the coil, and except that the second extended wire 32 and the second external terminal 42 are not provided.

The first inductor component 1A and the second inductor component 1B are arrayed on the same plane orthogonal to the axis L such that the axes L of the respective coils 15F are parallel to each other. Specifically, the first inductor component 1A and the second inductor component 1B are electrically independent. The first external terminal 41 and the third external terminal 43 of the first inductor component 1A and the first external terminal 41 and the third external terminal 43 of the second inductor component 1B are linearly arrayed along a direction orthogonal to the axis L.

According to the above-described configuration, the inductor components 1A and 1B having the same configurations as that of the inductor component 1 according to the sixth embodiment are provided. Therefore, it is possible to achieve both the size reduction and the inductance value of the inductor components 1A and 1B. As a result, it is possible to achieve both the size reduction and the inductance value of the inductor array 5.

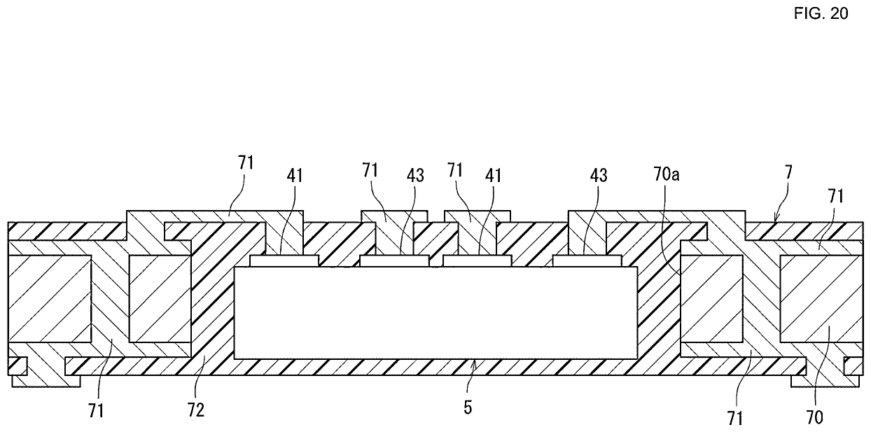

FIG. 20 is a cross-sectional view showing a state where the inductor array 5 is incorporated into the substrate 7. In FIG. 20, for convenience, the inductor array 5 is not hatched. As shown in FIG. 20, the inductor array 5 is incorporated into the substrate 7. The substrate 7 includes a core material 70, a wiring portion 71, and a resin member 72. The inductor array 5 is disposed inside the through-hole 70a of the core material 70. The resin member 72 seals the inductor array 5 and the substrate 7. The wiring portion 71 is provided to extend to the core material 70 and the resin member 72, and is connected to the external terminals 41 and 43 of the inductor array 5. In this manner, it is possible to achieve both the size reduction and the inductance value of the inductor array 5. Therefore, it is possible to achieve both the size reduction and the inductance value of the substrate 7.

### Ninth Embodiment

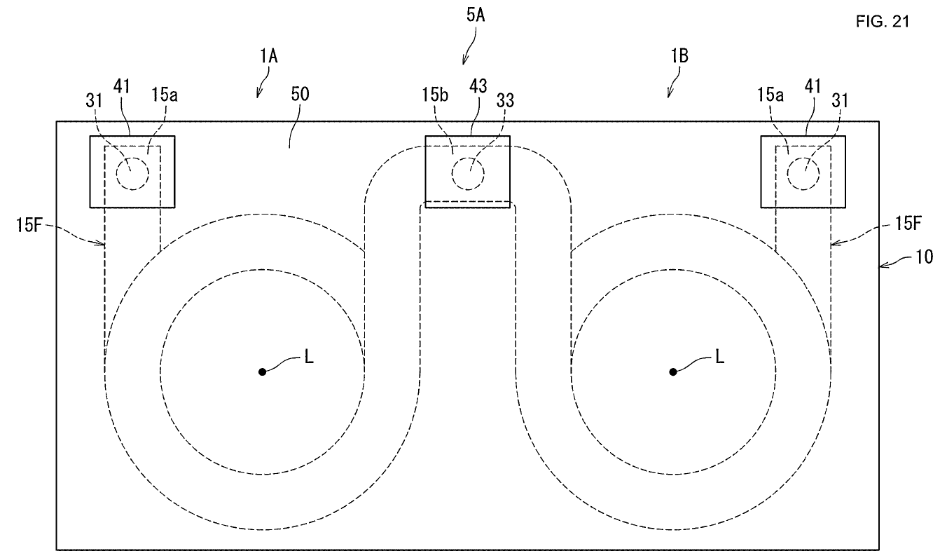

FIG. 21 is a plan view showing an embodiment of the inductor array. A ninth embodiment is different from the eighth embodiment in the disposition of the coils. The different configuration will be described below. Other configurations are the same configurations as those of the eighth embodiment, and the same reference numerals as those of the eighth embodiment will be assigned, and description thereof will be omitted.

As shown in FIG. 21, in an inductor array 5A, the first inductor component 1A and the second inductor component 1B are electrically connected in series. Specifically, the second end portion 15b of the coil 15F of the first inductor component 1A and the second end portion 15b of the coil 15F of the second inductor component 1B are common members. That is, the first inductor component 1A and the second inductor component 1B have the common third extended wire 33 and the common third external terminal 43. In this way, the inductor array 5A includes two sets of the first extended wire 31 and the first external terminal 41, and one set of the third extended wire 33 and the third external terminal 43.

According to the above-described configuration, in addition to the advantageous effect of the inductor array 5 of the eighth embodiment, the size of the inductor array 5A can be reduced by using the members in common.

The present disclosure is not limited to the above-described embodiments, and can be modified as appropriate within the scope not departing from the concept of the present disclosure. For example, respective characteristic points of the first to ninth embodiments may be combined in various ways.

In the embodiment, the coil includes the insulator, but the insulator is not an essential configuration. When the insulator is not provided, a manufacturing process can be simplified.

In the embodiment, in the cross section including the axis of the coil, each shape of the first wiring portion and the second wiring portion is the trapezoidal shape. However, the cross-sectional shapes of the first wiring portion and the second wiring portion are not particularly limited as long as the shapes satisfy the above-described disposition relationship between the first end of the first end surface and the second end surface. In addition, in the embodiment, in the cross section including the axis of the coil, each shape of the third wiring portion and the fourth wiring portion is the rectangular shape or the trapezoidal shape. However, each shape of the third wiring portion and the fourth wiring portion is not particularly limited, and may be a shape other than the rectangular shape or the trapezoidal shape.

In the embodiment, in the cross section including the axis of the coil, the coil wire includes the four layers of the first to fourth wiring portions, but may include two layers, three layers, or five or more layers of the wiring portions.

In the sixth embodiment, the coil is applied to the inductor component, but the coil may be applied to an electronic component such as a transformer. In this case, the inner magnetic path of the coil may be an air core.

In the eighth embodiment, the inductor array uses only the coil corresponding to the coil of the first embodiment. However, the inductor array may use the coil corresponding to the coil of the first embodiment and the coil corresponding to any coil of the second to fifth embodiments, or may use only the coil corresponding to any coil of the second to fifth embodiments. In addition, the inductor array may have three or more inductor components.

In the eighth embodiment, the first inductor component and the second inductor component are arrayed on the same plane orthogonal to the axis such that the axes of the respective coils are parallel to each other. However, as long as the first inductor component and the second inductor component are arrayed on the same plane, the axes of the respective coils do not need to be parallel to each other.

### REFERENCE SIGNS LIST

1 inductor component
1A first inductor component
1B second inductor component
5, 5A inductor array
7 substrate
10 Element body
10a first surface
10b second surface
15, 15A, 15B, 15C, 15D, 15E, 15F coil
15a first end portion
15b second end portion
20, 20A, 20B, 20C, 20D, 20E coil wire
21, 21A, 21B, 21C, 21D, 21E first wiring portion
22, 22A, 22B, 22C, 22D, 22E second wiring portion
23, 23A, 23B, 23C, 23D, 23E third wiring portion
24, 24A, 24B, 24C, 24D, 24E fourth wiring portion
201 to 208 first to eighth end surfaces
25 to 27 connection conductor layer
31 to 33 first to third extended wires
301 to 304 first to fourth side surfaces
41 to 43 first to third external terminals
50 insulation film
60, 60D insulator
61 to 63 first to third insulation layers
65 base insulation layer
81 mold
D1 first direction
D2 second direction
L axis of coil
SL1 to SL4 straight line
23W maximum width of third wiring portion
24W maximum width of fourth wiring portion
21t to 24t thicknesses of first to fourth wiring portions
201L to 204L lengths of first to fourth end surfaces
21CA to 24CA cross-sectional area of first to fourth wiring portions
e1 to e4 first end to fourth end

1. A coil comprising:
a coil wire spirally wound along an axis, wherein, in a cross section including the axis, the coil wire includes:
a first wiring portion and a second wiring portion which are aligned along the axis,
the first wiring portion is in a first outermost side portion in a direction of the axis, and the second wiring portion is in a second outermost side portion in the direction of the axis,
the first wiring portion includes
a first end surface on a side in a first direction from the first wiring portion toward the second wiring portion which is the direction of the axis, and
a second end surface on a side in a second direction opposite to the first direction,
the second wiring portion includes
a third end surface on the side in the first direction, and
a fourth end surface on the side in the second direction,
the first end surface includes a first end in an inner side portion in a radial direction of the coil wire, and
the second end surface is in an outer side portion in the radial direction of the coil wire with respect to a straight line passing through the first end and parallel to the direction of the axis.

2. The coil according to claim 1,
wherein in the cross section including the axis, the first end surface includes a second end in the outer side portion in the radial direction of the coil wire, and
the second end surface is in the inner side portion in the radial direction of the coil wire with respect to a straight line passing through the second end and parallel to the direction of the axis.

3. The coil according to claim 1, wherein in the cross section including the axis, a length of the second end surface is shorter than a length of the first end surface.

4. The coil according to claim 3, wherein in the cross section including the axis, the length of the second end surface is equal to or longer than 80% and equal to or shorter than 95% of the length of the first end surface.

5. The coil according to claim 1,
wherein in the cross section including the axis, the fourth end surface includes a third end in the inner side portion in the radial direction, and
the third end surface is in the outer side portion in the radial direction with respect to a straight line passing through the third end and parallel to the direction of the axis.

6. The coil according to claim 5, wherein in the cross section including the axis, a length of the third end surface is shorter than a length of the fourth end surface.

7. The coil according to claim 6, wherein in the cross section including the axis, the length of the third end surface is equal to or longer than 80% and equal to or shorter than 95% of the length of the fourth end surface.

8. The coil according to claim 1, wherein in the cross section including the axis, the coil wire further includes a third wiring portion between the first wiring portion and the second wiring portion.

9. The coil according to claim 8, wherein a length of the first end surface is equal to a maximum width of the third wiring portion in the radial direction of the coil wire, or is shorter than the maximum width of the third wiring portion.

10. The coil according to claim 8, wherein in the cross section including the axis, a length of the fourth end surface is equal to a maximum width of the third wiring portion in the radial direction of the coil wire, or is shorter than the maximum width of the third wiring portion.

11. The coil according to claim 8,
wherein in the cross section including the axis, the third wiring portion includes a fifth end surface on the side in the first direction, and a sixth end surface on the side in the second direction, and
a length of the sixth end surface is shorter than a length of the fifth end surface, and is equal to a length of the first end surface, or is longer than a length of the first end surface.

12. The coil according to claim 9, wherein in the cross section including the axis, a thickness of the first wiring portion is thicker than a thickness of the third wiring portion.

13. The coil according to claim 8, wherein in the cross section including the axis, a cross-sectional area of the first wiring portion is equal to or more than 0.8 times and equal to or less than 1.2 times a cross-sectional area of the third wiring portion.

14. The coil according to claim 8,
wherein in the cross section including the axis, the coil wire further includes a fourth wiring portion between the third wiring portion and the second wiring portion,
a length of the first end surface is equal to a maximum width of the fourth wiring portion in the radial direction of the coil wire, or is shorter than the maximum width of the fourth wiring portion, and
a length of the fourth end surface is equal to the maximum width of the fourth wiring portion in the radial direction of the coil wire, or is shorter than the maximum width of the fourth wiring portion.

15. The coil according to claim 14,
wherein in the cross section including the axis, the fourth wiring portion includes a seventh end surface on the side in the first direction and an eighth end surface on the side in the second direction, and
a length of the seventh end surface is shorter than a length of the eighth end surface, and is equal to the length of the fourth end surface, or is longer than the length of the fourth end surface.

16. The coil according to claim 14,
wherein in the cross section including the axis, a thickness of the first wiring portion is thicker than each thickness of the third wiring portion and the fourth wiring portion, and
a thickness of the second wiring portion is thicker than each thickness of the third wiring portion and the fourth wiring portion.

17. The coil according to claim 14,
wherein in the cross section including the axis, a cross-sectional area of the first wiring portion is equal to or more than 0.8 times and equal to or less than 1.2 times each cross-sectional area of the third wiring portion and the fourth wiring portion, and
a cross-sectional area of the second wiring portion is equal to or more than 0.8 times and equal to or less than 1.2 times each cross-sectional area of the third wiring portion and the fourth wiring portion.

18. An inductor component comprising:
an element body including a magnetic material; and
the coil according to claim 1 inside the element body.

19. The inductor component according to claim 18,
wherein in the cross section including the axis, the first wiring portion includes a first side surface and a second side surface which connect the first end surface and the second end surface,
the second wiring portion includes a third side surface and a fourth side surface which connect the third end surface and the fourth end surface, and
at least one side surface of the first side surface, the second side surface, the third side surface, and the fourth side surface has a recessed shape recessed inward of the first wiring portion or the second wiring portion.

20. An inductor array comprising:
a plurality of the inductor components according to claim 18,
wherein the plurality of inductor components are arrayed on the same plane.
